(19) United States
(12) Patent Application Publication
(10) Pub. No.: US 2015/0257305 A1
(43) Pub. Date: Sep. 10, 2015

(54) TV HEAT SHIELD ASSEMBLY AND METHODS OF USE

(71) Applicant: Matthew Barker, Perry, GA (US)

(72) Inventor: Matthew Barker, Perry, GA (US)

(21) Appl. No.: 14/203,132

(22) Filed: Mar. 10, 2014

(51) Int. Cl. H05K 7/20

(52) U.S. Cl. CPC H05K 7/20145

(57) ABSTRACT

A ventilation system having a conduit, a grating having openings or ventilation holes to capture rising radiant heat, a filter wherein the filter is affixed proximate the openings or ventilation holes; a first fan wherein the first fan is mounted on the first end of the conduit; a second fan wherein the second fan is mounted on the second end of the conduit.

### TECHNICAL FIELD

The disclosure relates generally to a heat shield and heat dispersion and more specifically the disclosure relates to a heat shield assembly and method of dispersion of radiant heat.

### BACKGROUND

Various heat shields and heat dispersion mechanism are known in the prior art, such as exhaust manifolds which have an aluminum shield mounted in close proximity to the radiant heat source of the exhaust to protect motor and other engine and vehicle parts from the high temperatures of the exhaust. In residential construction, it has become popular to mount LCD and plasma flat screen televisions above their fireplace since the fireplace is centered in the room and has a large open surface area to accommodate the flat screen TV. This activity begs the question “Should one mount a flat screen TV above the fireplace?” due the radiant heat generated when the fireplace is in use and such radiant heat rises up into the flat screen television. With a large investment in today's LCD and plasma flat screen televisions an owner would like to ensure their television is not damaged from the radiant heat of the fireplace, care must be taken to ensure heat generated by the fireplace is redirected away from television.

One previous approach is to build a mantel into the fireplace during home construction and such mantel acts as a diverter of the radiant heat generated by the fireplace. One disadvantage of this approach is that this action requires advanced construction during the building of the fireplace or a retrofit construction of the existing fireplace. Moreover, the integration of a mantel between the fireplace and the above mounted television may divert some of the rising radiant heat from the fireplace but most of the heat builds up under the fireplace and eventually works around the mantel and rises up into the television.

Various ventilation, heating and air conditioning systems are known in the prior art, for example, there are ventilation systems for window frames or door frames to move air either inside to outside or outside to inside depending on the outside ambient temperature. Such systems include an internal air conduit and fans to move air in the desired direction, such as to move air from the front side of the panel to the back side. One disadvantage of this approach is that it directs air from the front side of the panel to the back side and does not disperse rising radiant heat.

Another prior art example is a window or indoor air-conditioner. Such systems include a built in heat exchanger, ventilation system, and an air inlet and outlet. However, such systems serve as an air-conditioner as opposed to a ventilation system to deflect or disperse rising radiant heat.

Therefore, it is readily apparent that there is a recognized unmet need for a TV heat shield and methods of use that is easy to install and is capable of collecting rising radiant heat from a fireplace and dispersing the heat away from an above positioned television.

### BRIEF SUMMARY

Briefly described, in example embodiment, the present apparatus overcomes the above-mentioned disadvantage, and meets the recognized need for a TV heat shield assembly and methods of use including, in general, a ventilation system built into a rectangular conduit wherein the rectangular conduit includes a top side, a left side and a right side, as viewed from a cross section, a grating having openings or ventilation holes to capture rising radiant heat, a filter wherein the filter is affixed proximate the openings or ventilation holes; a first fan wherein the first fan is mounted on the first end of the rectangular conduit; a second fan wherein the second fan is mounted on the second end of the rectangular conduit and, thus, functions as an improved TV heat shield and method of dispersing rising radiant heat from a fireplace positioned below the TV.

According to its major aspects and broadly stated, a TV heat shield assembly and methods of use including, in general, a ventilation system built into a conduit wherein the conduit comprises a first end and a second end, top side and a bottom side and wherein the bottom side further includes openings for ventilation; a filter wherein the filter is affixed above the openings for ventilation holes; a first fan wherein the first fan is mounted on the first end of the conduit; a second fan wherein the second fan is mounted on the second end of the conduit; and an electric power source for the first fan and the second fan, and thus functions as a low installation cost improved TV heat shield and method of dispersing rising radiant heat from a fireplace positioned below.

In a preferred exemplary embodiment, a heat shield assembly, the assembly includes a conduit, wherein the conduit is formed having a first conduit end and a second conduit end, a vent configured therein a section of the conduit and disposed between the first conduit end and the second conduit end, and two or more fans, the two or more fans includes a first fan positioned proximate the first conduit end and a second fan positioned proximate the second conduit end.

In a further exemplary embodiment, a heat shield for a television vertically positioned above a fireplace that generates a rising hot air, the system includes a conduit positioned between the television and the fireplace, wherein the conduit is formed having a first conduit end and a second conduit end, a vent configured therein a section of the conduit to capture the rising hot air and the vent is disposed between the first conduit end and the second conduit end, and two or more fans, the two or more fans includes a first fan positioned proximate the first conduit end and a second fan positioned proximate the second conduit end to discharge the hot air away from the television.

In still a further exemplary embodiment of the method of dispersing a heated air from a fireplace away from an above mounted television, including the steps of providing a heat shield assembly having a conduit, wherein the conduit is formed having a first conduit end and a second conduit end, a vent configured therein a section of the conduit and disposed between the first conduit end and the second conduit end, and two or more fans, the two or more fans includes a first fan positioned proximate the first conduit end and a second fan positioned proximate the second conduit end, positioning the heat shield assembly between the fireplace and the above mounted television, pulling the heated air rising from the fireplace into the vent of the conduit, discharging the heated air from first conduit end away from the television, and discharging the heated air from second conduit end away from the television.

Accordingly, a feature of the TV heat shield assembly and method of dispersing the rising radiant heat is the ability to shield a fireplace mounted TV from rising radiant heat from a fireplace below.

Another feature of the TV heat shield assembly and method of dispersing the rising radiant heat is the ability to disperse rising radiant heat from a TV mounted above a fireplace.

Still another feature of the TV heat shield assembly and method of dispersing the rising radiant heat is its ability to enable quick installation of the TV heat shield without any construction or retrofitting of the fireplace or the vertical surface above the fireplace.

Yet another feature of the TV heat shield assembly and method of dispersing the rising radiant heat is its ability to extend the life of an LCD or plasma flat screen television positioned above a fireplace by reducing the amount of radiant heat exposure of the television.

Yet another feature of the TV heat shield assembly and method of dispersing the rising radiant heat is its ability to integrate speakers or a sound bar into the TV heat shield to provide an improved sound system with the TV heat shield installation.

Yet another feature of the TV heat shield assembly and method of dispersing the rising radiant heat is its ability to maintain a television within its optimum temperature operating range.

These and other features of the TV heat shield assembly and method of dispersing the rising radiant heat will become more apparent to one skilled in the art from the following Detailed Description of the Embodiments and Claims when read in light of the accompanying drawing Figures.

### BRIEF DESCRIPTION OF THE DRAWINGS

The present TV heat shield assembly and methods of use will be better understood by reading the Detailed Description of the embodiments with reference to the accompanying drawing figures, in which like reference numerals denote similar structure and refer to like elements throughout, and in which:

FIG. 1, 1.1 is a perspective view of TV heat shield assembly and includes FIG. 1.2 a schematic diagram of fan motor circuit;

FIG. 2 is an exploded component view of the TV heat shield assembly of FIG. 1.1;

FIG. 3 is a front view of the TV heat shield assembly of FIG. 1, shown positioned on a fireplace wall between a fireplace and an above mounted television showing heat dispersion arrows;

FIG. 4 is a front view of a TV speaker bar;

FIG. 5 is a front view of the TV heat shield assembly of FIG. 1 and TV speaker bar of FIG. 4, shown positioned on a fireplace wall between a fireplace and an above mounted television; and

FIG. 6 is a flow diagram of a method of utilizing TV heat shield assembly to disperse rising radiant heat away from a television.

It is to be noted that the drawings presented are intended solely for the purpose of illustration and that they are, therefore, neither desired nor intended to limit the disclosure to any or all of the exact details of construction shown, except insofar as they may be deemed essential to the claimed invention.

### DETAILED DESCRIPTION

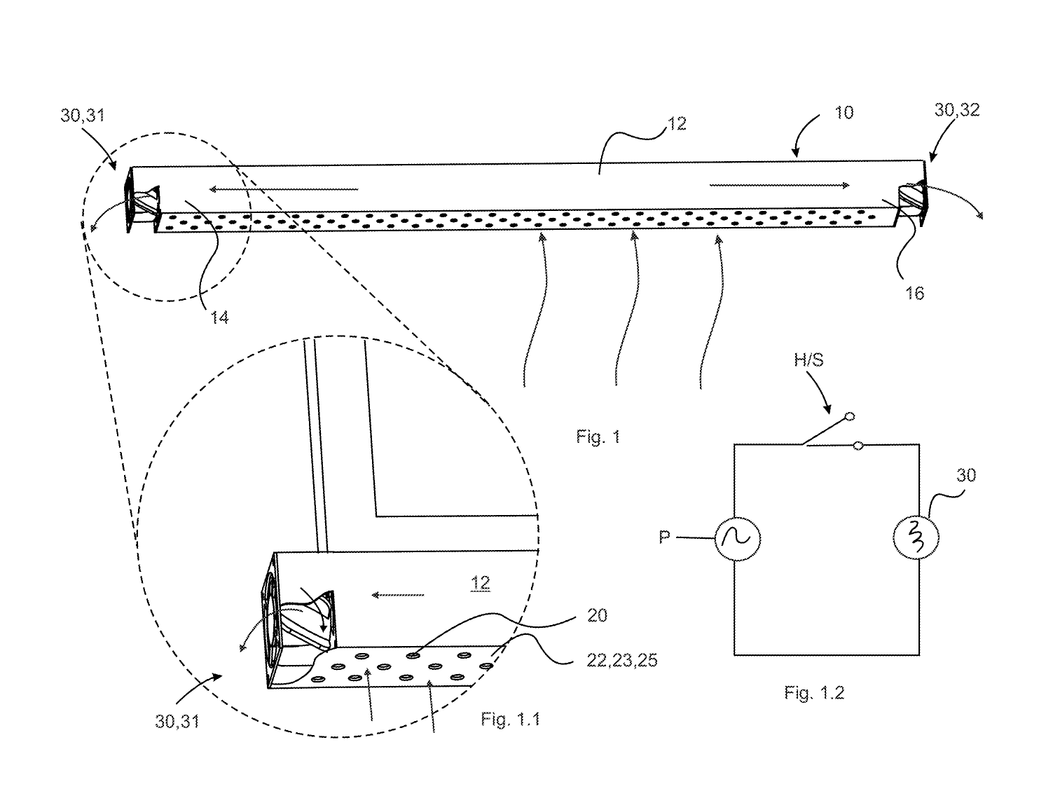

In describing the exemplary embodiments of the present disclosure, as illustrated in FIGS. 1-6 specific terminology is employed for the sake of clarity. The present disclosure, however, is not intended to be limited to the specific terminology so selected, and it is to be understood that each specific element includes all technical equivalents that operate in a similar manner to accomplish similar functions. Embodiments of the claims may, however, be embodied in many different forms and should not be construed to be limited to the embodiments set forth herein. The examples set forth herein are non-limiting examples, and are merely examples among other possible examples.

Referring now to FIGS. 1-6 by way of example, and not limitation, therein is illustrated an example embodiment heat shield, such as TV heat shield assembly 10, wherein TV heat shield assembly 10 includes conduit 12, vent 22, and fans 30.

Referring now to FIGS. 1 and 1.1, by way of example, and not limitation, there is illustrated a perspective view of TV heat shield assembly 10, wherein TV heat shield assembly 10 preferably includes a duct or tube, such as conduit 12, wherein conduit 12 further includes a section or surface having plurality of apertures 20 formed, drilled, or machined and configured such as, vent 22 configured as a section of conduit 12 and disposed between first conduit end 14 and second conduit end 16 of conduit 12, two or more fans 30, such as first fan 31 and second fan 32, positioned proximate first conduit end 14 and second conduit end 16 of conduit 12, respectively.

It is recognized herein that conduit 12 may be configured with a square or round cross-section or other configuration known in the art.

It is further recognized herein that conduit 12 may include a removeable grating or grille 23 disposed in a slotted groove therein conduit 12 or releasably affixed thereto conduit 12.

It is still further contemplated herein that conduit may include a removeable filter 25 to filter air entering conduit 12.

It is still further contemplated herein that vent 22 may be formed of such removeable filter 25 to filter air entering conduit 12.

It is still further contemplated herein that vent 22 may be formed of such removeable filter 25 may be disposed in a slotted section of or releasably affixed thereto conduit 12.

Conduit 12 is preferably formed of a suitable material, such as plastic, polymer, fiber, aluminum, steel, alloy, wood or combinations thereof or the like, capable of providing structure to conduit 12. Moreover, conduit 12 may be corrugated to provide additional strength or structure to the linear length of conduit 12. Preferably, the material includes other suitable characteristics, such as durability, rust-resistance, light weight, heat-resistance, chemical inertness, oxidation resistance, ease of workability, or other beneficial characteristic understood by one skilled in the art.

Referring now to FIG. 1.2, by way of example, and not limitation, there is illustrated a schematic diagram of two or more fans 30. Preferably a circuit diagram of two or more fans 30 includes a power supply, such as power source P, which is preferably direct current but alternatively may include alternating current, and switch H/S, which is preferably configured as temperature sensitive switch, which triggers, closes, or connects the normally open circuit when a specific ambient temperature is present or reached. Such ambient temperature trigger is preferably approximately 100° F. but other temperatures are contemplated herein.

It is recognized herein that power source P may include power from television TV supplying electric power to TV heat shield assembly 10.

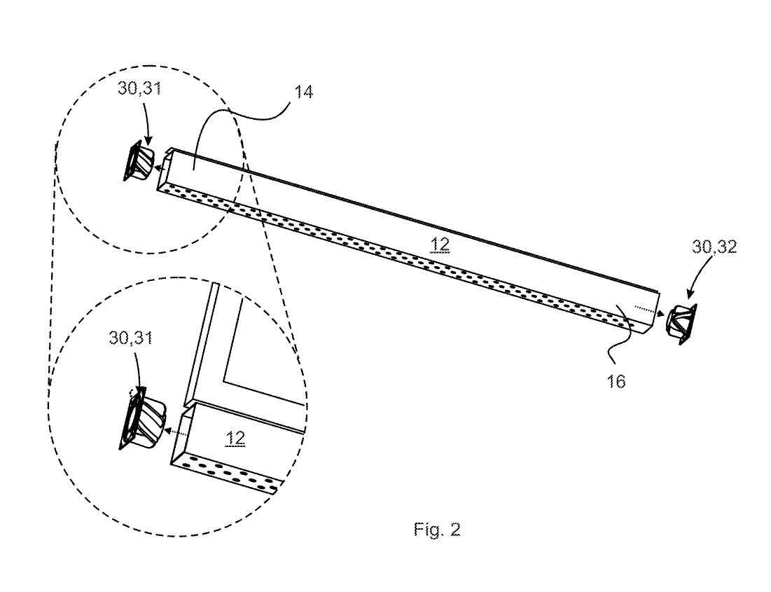

Referring now to FIG. 2, by way of example, and not limitation, there is illustrated an exploded view of TV heat shield assembly 10 having two or more fans 30, such as first fan 31 and second fan 32, positioned proximate first conduit end 14 and second conduit end 16 of conduit 12, respectively and first fan 31 is preferably configured to fit, mate up, or be disposed therein first conduit end 14 and second fan 32 is preferably configured to fit, mate up, or be disposed therein second conduit end 16.

It is contemplated herein that two or more fans 30 may be affixed to first conduit end 14 and second conduit end 16 of conduit 12.

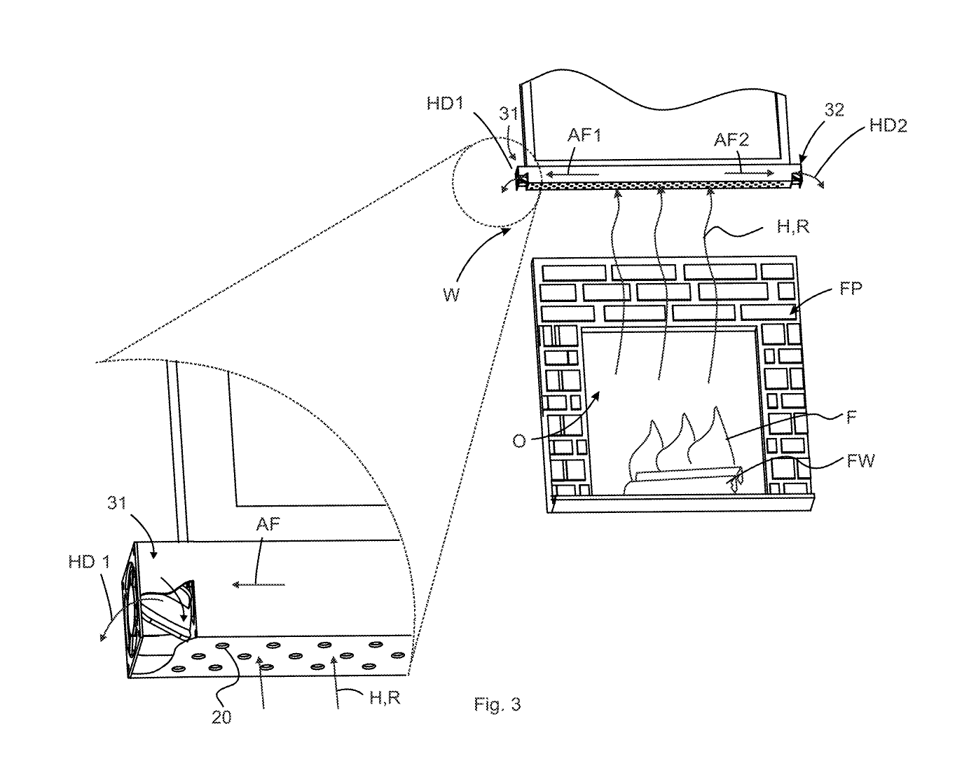

Referring now to FIG. 3, by way of example, and not limitation, there is illustrated fireplace FP, wherein fire F is preferably generating heat H. Moreover, LCD, plasma, or flat screen, or other viewing device, such as television TV and is preferably mounted to wall W vertically positioned above fireplace FP. TV heat shield assembly 10 is also preferably positioned on wall W or affixed thereto television TV between fireplace FP and the above television TV. When fireplace FP is in use with a fire F heat H is generated therein and radiates out opening O of fireplace FP heating the ambient air in front of fireplace FP. Heated ambient air rises upward along wall W to television TV, shown by air rising arrows R. When in use, heated ambient air, shown by air rising arrows R (rising hot air) enters or is pulled into TV heat shield assembly 10 thru apertures 20 of vent 22. First fan 31 pulls heated ambient air, shown by air flow arrow AF1 toward first conduit end 14 and discharges heated ambient air, shown by heated ambient air discharge arrow HD1 away from television TV and second fan 32 pulls heated ambient air, shown by air flow arrow AF2 toward second conduit end 16 and discharges heated ambient air, shown by heated ambient air discharge arrow HD2 away from television TV, respectively.

It is recognized herein that television TV can operate safely in rooms or areas in which temperatures range from 50° F. to 104° F. (10° C. to 40° C.)(the “Operating Temperature”). Operating Temperatures outside the manufactures recommendations will negatively affect and possibly damage television TV. In general, firewood burns at temperature of 900° F. to 1200° F. (fire F heat H) producing heated ambient air above the Operating Temperature of television TV, shown by air rising arrows R.

It is contemplated herein that TV heat shield assembly 10 preferably shields and/or disperses heated ambient air, shown by air rising arrows R away from television TV to enable television TV to maintain a safe ambient air Operating Temperature while fireplace FP operates below television TV. It is further contemplated herein that TV heat shield assembly 10 preferably extends the life of television TV positioned above a fireplace by reducing the amount of radiant heat exposure, heated ambient air, shown by air rising arrows R, to television TV. It is still further contemplated herein that TV heat shield assembly 10 preferably maintains television TV within its optimum Operating Temperature.

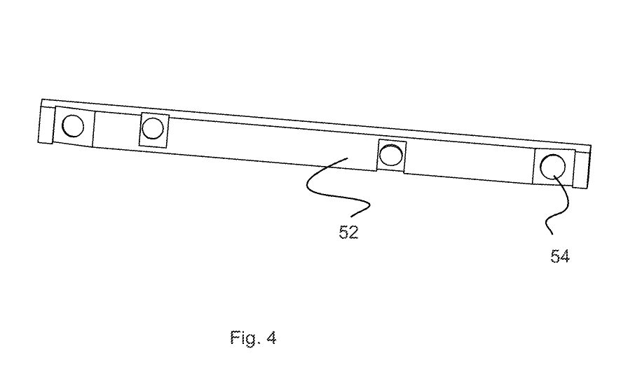

Referring now to FIG. 4, by way of example, and not limitation, there is illustrated a front view of external TV speakers, such as soundbar 50, wherein soundbar 50 preferably includes housing 52 and one or more speakers 54 positioned therein the linear length of housing 52. Preferably one or more speakers 54 include one or more directional speakers to widen the sound field to mimic surround sound for television TV. It is recognized herein that an output audio signal from television TV may be connected or transmitted to soundbar 50 to enable soundbar 50 to broadcast sound for television TV. It is further recognized herein that soundbar 50 may receive electrical power from an electrical connection to television TV, such as from an alternating current or direct current outlet or a USB power connection.

It is recognized herein that soundbar 50 can operate safely in rooms or areas in which temperatures range from 50° F. to 104° F. (10° C. to 40° C.)(the “Operating Temperature”).

It is recognized herein that soundbar 50 may need to be insulated from conduit 12 due to the elevated temperatures of heated ambient air, shown by air flow arrow AF1 and AF2. Therefore, insulation material 70 may be placed therebetween conduit 12 and soundbar 50 to insulate soundbar 50 from heated ambient air, shown by air flow arrow AF1 and AF2.

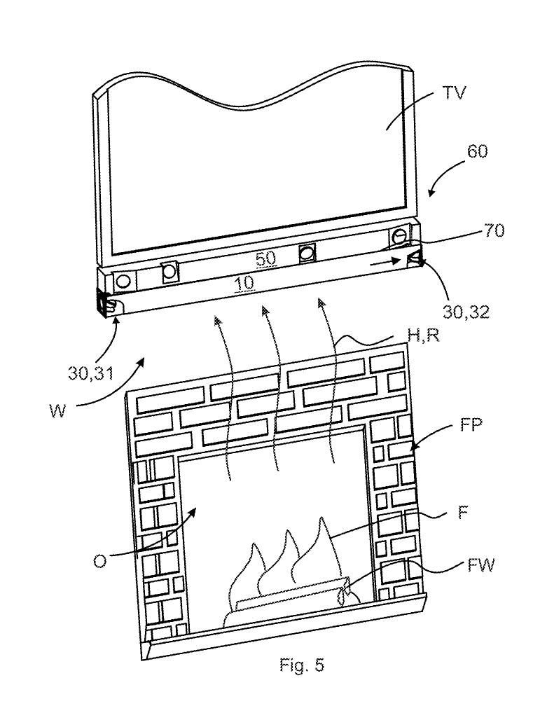

Referring now to FIG. 5, by way of example, and not limitation, there is illustrated TV heat shield assembly 10 and soundbar 50, as disposed proximate, combined, or integral with the other. Moreover, TV heat shield assembly with soundbar 60 is preferably positioned on wall W or affixed thereto television TV between fireplace FP and the above television TV. TV heat shield assembly with soundbar 60 preferably performs and operates as described herein in FIGS. 1-4.

It is contemplated herein that combined or integral TV heat shield assembly with soundbar 60 preferably provides an improved sound system for television TV and TV heat shield assembly 10 features set forth herein in FIGS. 1-4. It is still further contemplated herein that TV heat shield assembly with soundbar 60 preferably maintains television TV within its optimum Operating Temperature.

It is contemplated herein that an insulation material 70 may be positioned between soundbar 50 and TV heat shield assembly 10 preferably to insulate or protect soundbar 50 from heated ambient air, shown by air flow arrow AF1/AF2.

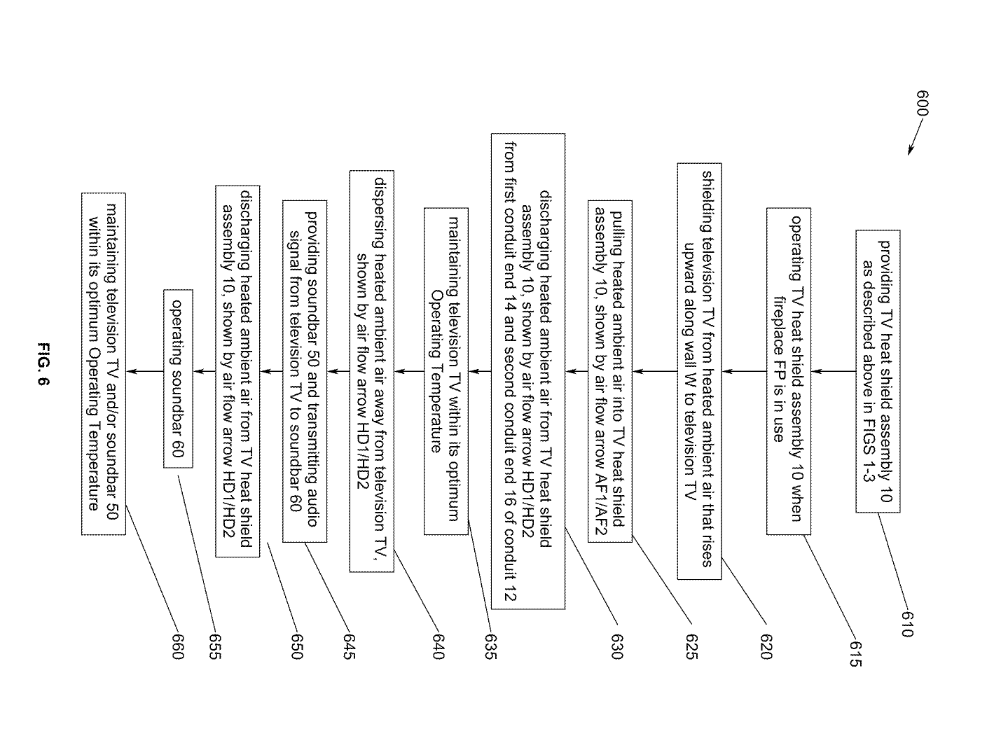

Referring now to FIG. 6, there is illustrated a flow diagram 600 of a method of dispersing heated ambient air (heated air) from fireplace FP, shown by air rising arrows R toward television TV. In block or step 610, providing TV heat shield assembly 10, which includes, conduit 12, wherein conduit 12 further includes a section or surface having plurality of apertures 20 formed, drilled, or machined and configured such as, vent 22, two or more fans 30, such as first fan 31 and second fan 32, positioned proximate first conduit end 14 and second conduit end 16 of conduit 12, respectively as described above in FIGS. 1-3. In block or step 615, positioning TV heat shield assembly 10 between fireplace FP and above mounted television TV and operating TV heat shield assembly 10 when fireplace FP is in use with a fire F heat H is generated therein and radiates out opening O of fireplace FP heating the ambient air in front of fireplace FP. In block or step 620, shielding television TV from heated ambient air (heated air) that rises upward along wall W to television TV, shown by air rising arrows R. In block or step 625, pulling heated ambient air (heated air) that rises upward along wall W into vent 22 of conduit 12, shown by air flow arrow AF1/AF2. In block or step 630, discharging heated ambient air from TV heat shield assembly 10, shown by air flow arrow HD1/HD2 from first conduit end 14 and second conduit end 16 of conduit 12, respectively. In block or step 635, maintaining television TV within its optimum Operating Temperature. In block or step 640, dispersing heated ambient air away from television TV, shown by air flow arrow HD1/HD2. In block or step 645, providing soundbar 50, wherein soundbar 50 preferably includes housing 52 and one or more speakers 54 positioned therein the linear length of housing 52, as combined or integral TV heat shield assembly with soundbar 60 and transmitting audio signal from television TV to soundbar 60. In block or step 650, discharging heated ambient air from TV heat shield assembly 10, shown by air flow arrow HD1/HD2. In block or step 655, operating soundbar 60. In block or step 660, maintaining television TV and/or soundbar 60 within its optimum Operating Temperature.

The foregoing description and drawings comprise illustrative embodiments of the present invention. Having thus described exemplary embodiments, it should be noted by those ordinarily skilled in the art that the within disclosures are exemplary only, and that various other alternatives, adaptations, and modifications may be made within the scope of the present invention. Merely listing or numbering the steps of a method in a certain order does not constitute any limitation on the order of the steps of that method. Many modifications and other embodiments of the invention will come to mind to one ordinarily skilled in the art to which this invention pertains having the benefit of the teachings presented in the foregoing descriptions and the associated drawings. Although specific terms may be employed herein, they are used in a generic and descriptive sense only and not for purposes of limitation. Moreover, the present invention has been described in detail; it should be understood that various changes, substitutions and alterations can be made thereto without departing from the spirit and scope of the invention as defined by the appended claims. Accordingly, the present invention is not limited to the specific embodiments illustrated herein, but is limited only by the following claims.

What is claimed is:

1. A heat shield assembly, the assembly comprising:
a conduit, wherein said conduit is formed having a first conduit end and a second conduit end;
a vent configured therein a section of said conduit and disposed between said first conduit end and said second conduit end; and
two or more fans, said two or more fans includes a first fan positioned proximate said first conduit end and a second fan positioned proximate said second conduit end.

2. The heat shield assembly of claim 1, wherein said vent further comprises a plurality of apertures.

3. The heat shield assembly of claim 2, wherein said vent further comprises a removeable grille.

4. The heat shield assembly of claim 3, wherein said conduit further comprises a slotted groove, wherein said removeable grille is disposed therein said slotted groove.

5. The heat shield assembly of claim 1, wherein said vent further comprises a removeable filter.

6. The heat shield assembly of claim 1, further comprises a television having a power source, said power source supplying electric power to said two or more fans.

7. The heat shield assembly of claim 6, further comprises a temperature sensitive switch to regulate electric power to said two or more fans.

8. The heat shield assembly of claim 1, wherein said first conduit end is configured to mate with said first fan disposed therein said first conduit end and said second conduit end is configured to mate with said second fan disposed therein said second conduit end.

9. The heat shield assembly of claim 1, further comprises a soundbar disposed proximate said conduit.

10. The heat shield assembly of claim 9, further comprises a television having an audio signal, said audio signal is transmitted to said soundbar.

11. The heat shield assembly of claim 9, further comprises an insulation material positioned therebetween said soundbar and said conduit.

12. A heat shield for a television vertically positioned above a fireplace that generates a rising hot air, the system comprising:
a conduit positioned between the television and the fireplace, wherein said conduit is formed having a first conduit end and a second conduit end;
a vent configured therein a section of said conduit to capture the rising hot air and said vent is disposed between said first conduit end and said second conduit end; and
two or more fans, said two or more fans includes a first fan positioned proximate said first conduit end and a second fan positioned proximate said second conduit end to discharge the hot air away from the television.

13. The system of claim 12, wherein said vent further comprises a plurality of apertures.

14. The system of claim 13, wherein said vent further comprises a removeable grille.

15. The system of claim 14, wherein said conduit further comprises a slotted groove, wherein said removeable grille is disposed therein said slotted groove.

16. The system of claim 13, wherein said vent further comprises a removeable filter.

17. The system of claim 12, further comprises a television having a power source, said power source supplying electric power to said two or more fans.

18. The system of claim 17, further comprises a temperature sensitive switch to regulate electric power to said two or more fans.

19. The system of claim 12, wherein said first conduit end is configured to mate with said first fan disposed therein said first conduit end and said second conduit end is configured to mate with said second fan disposed therein said second conduit end.

20. The system of claim 12, further comprises a soundbar disposed proximate said conduit.

21. The system of claim 20, further comprises a television having an audio signal, said audio signal is transmitted to said soundbar.

22. The system of claim 20, further comprises an insulation material positioned therebetween said soundbar and said conduit.

23. A method dispersing a heated air from a fireplace away from an above mounted television, comprising the steps of:
providing a heat shield assembly having a conduit, wherein said conduit is formed having a first conduit end and a second conduit end, a vent configured therein a section of said conduit and disposed between said first conduit end and said second conduit end, and two or more fans, said two or more fans includes a first fan positioned proximate said first conduit end and a second fan positioned proximate said second conduit end;
positioning said heat shield assembly between the fireplace and the above mounted television;
pulling the heated air rising from the fireplace into said vent of said conduit;
discharging the heated air from first conduit end away from the television; and
discharging the heated air from second conduit end away from the television.

24. The method of claim 23, further comprising the step of maintaining the television within its Operating Temperature.

25. The method of claim 24, further comprises the step of providing a soundbar disposed proximate said conduit.

26. The system of claim 18, further comprises the step of transmitting an audio signal from the television to said soundbar.
